(19) United States
(12) Patent Application Publication
(10) Pub. No.: US 2026/0110960 A1
(43) Pub. Date: Apr. 23, 2026

(54) NANOIMPRINT MASK AND METHOD FOR MANUFACTURING THE SAME

(71) Applicant: TAIWAN SEMICONDUCTOR MANUFACTURING COMPANY, LTD., Hsinchu (TW)

(72) Inventors: Hsin-Chang LEE, Hsinchu County (TW); Pei-Cheng HSU, Taipei City (TW); Ching-Fang YU, Hsinchu City (TW); Chia-Jen CHEN, Hsinchu County (TW); Chien-Cheng CHEN, Hsinchu County (TW)

(73) Assignee: TAIWAN SEMICONDUCTOR MANUFACTURING COMPANY, LTD., Hsinchu (TW)

(21) Appl. No.: 18/920,237

(22) Filed: Oct. 18, 2024

(51) Int. Cl. G03F 7/00; H01L 21/308; H01L 21/768

(52) U.S. Cl. CPC G03F 7/0002; H10P 50/695; H10W 20/032

(57) ABSTRACT

A method for manufacturing a mask is provided. The method includes depositing a buffer layer over a frontside surface of a substrate; depositing an etch stop layer over the buffer layer; depositing a mold layer over the etch stop layer; patterning a backside of the substrate to form a core-out portion and a frame portion surrounding the core-out portion, wherein a thickness of the frame portion is greater than a thickness of the core-out portion; and etching a relief pattern in the mold layer over the core-out portion of the substrate until reaching the etch stop layer.

### BACKGROUND

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate; therefore nano-fabrication becomes increasingly important. Nano-fabrication provides greater process control while allowing continued reduction of the minimum feature dimensions of the structures formed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing a master nanoimprint mask according to some embodiments of the present disclosure.

FIGS. 2-10 illustrate schematic views of intermediate stages in the manufacture of a master nanoimprint mask in accordance with some embodiments of the present disclosure.

FIGS. 11A-11C are schematic views of a nanoimprint lithography process using a master nanoimprint mask in accordance with some embodiments of the present disclosure.

FIG. 12 is a flow chart of a method for manufacturing a replica nanoimprint mask according to some embodiments of the present disclosure.

FIGS. 13-23 illustrate schematic views of intermediate stages in the manufacture of a replica nanoimprint mask in accordance with some embodiments of the present disclosure.

FIGS. 24A-24C are schematic views of a nanoimprint lithography process using a replica nanoimprint mask in accordance with some embodiments of the present disclosure.

FIGS. 25-31 illustrate schematic views of intermediate stages in the manufacture of a replica nanoimprint mask in accordance with some embodiments of the present disclosure.

FIGS. 32-35 illustrate schematic views of intermediate stages in the manufacture of a replica nanoimprint mask in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,”or “substantially”can be inferred if not expressly stated.

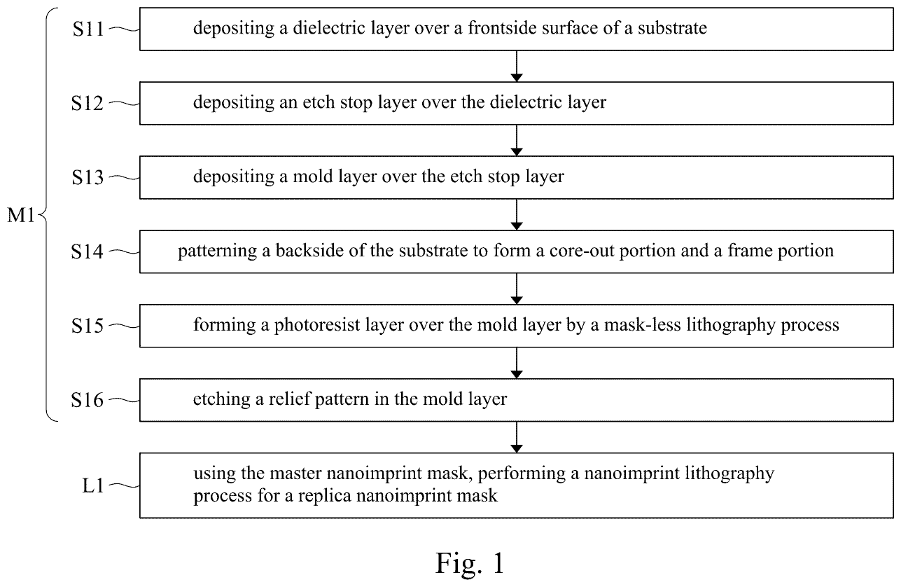

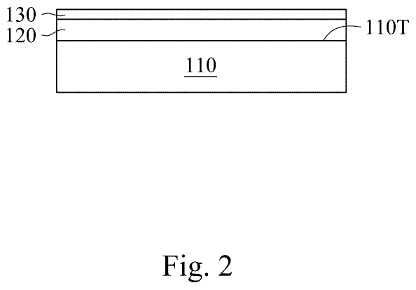

FIG. 1 is a flow chart of a method M1 for manufacturing a master nanoimprint mask according to some embodiments of the present disclosure. FIGS. 2-10 illustrate schematic views of intermediate stages in the manufacture of a master nanoimprint mask in accordance with some embodiments of the present disclosure. The method M1 includes steps S11-S16, followed by a nanoimprint lithography process using the master nanoimprint mask at step L1. It is understood that additional steps may be provided before, during, and after the steps S11-S16 shown in FIG. 1, and some of the steps described below can be replaced or eliminated for additional embodiments of the method. The order of the operations/processes may be interchangeable.

Reference is made to FIGS. 1 and 2. The method M1 begins at step S11 where a buffer layer 120 is deposited on a frontside surface 110T of a substrate 110. The substrate 110 may be formed of an optically transparent material, such as glass, quartz, an optically transparent resin such as poly (methyl methacrylate) (PMMA) or a polycarbonate resin, a transparent metal-deposited film, the like, or the combination thereof. The substrate 110 may be an electrical isolator. In some embodiments, the substrate 110 is amorphous. For example, the substrate 110 is an amorphous quartz substrate.

In some embodiments, the buffer layer 120 is an amorphous layer, and the substrate 110 and the buffer layer 120 forms an amorphous to amorphous structure, which may increase adhesion therebetween. The buffer layer 120 may also be referred to as an adhesion layer or a strain layer. The buffer layer 120 may include suitable dielectric material, such as Al₂O₃, SiO₂, Si₃N₄, SiN, other ceramics, the like, or the combination thereof. A polish process may be performed to planarize a frontside surface 110T of the substrate 110 before depositing the buffer layer 120 thereon. The buffer layer 120 can be deposited by physical vapor deposition (PVD), ion beam deposition (IBD), atomic layer deposition (ALD), plasma-enhanced ALD (PEALD), chemical vapor deposition (CVD), plasma-enhanced CVD (PECVD), the like, or the combination thereof.

The method M1 proceeds to step S12 where an etch stop layer 130 is deposited on the buffer layer 120. The etch stop layer 130 can be a conductive layer, thereby facilitating a e-beam particle inspection by avoiding the charging during inspection. For example, the etch stop layer 130 includes Al₂O₃, AlSiO, Ti doped SiO₂, TiO₂ doped SiO₂, Sn doped SiO₂, Mg doped SiO₂, Cu doped SiO₂, CrN, CrON, TaBO, TaBN, Ir, Pt, Rh, Ru, ITO, Carbon Nanotube (CNT) doped SiO₂. The etch stop layer 130 may be a metal--containing layer, such as a metal layer or a dielectric layer doped with metal particles/wires. In some embodiments, the etch stop layer 130 may be an amorphous layer, and the etch stop layer 130 and the buffer layer 120 forms an amorphous to amorphous film structure, which may increase adhesion therebetween. In some alternative embodiments, the etch stop layer 130 may be a polycrystalline layer. The etch stop layer 130 can be deposited by PVD, IBD, ALD, PEALD, CVD, PECVD, the like, or the combination thereof.

In absence of the buffer layer 120, lattice mismatch may occur between the etch stop layer 130 and the substrate 110, which induces stress. The stress may cause peeling between the substrate 110 and the etch stop layer 130 formed thereon.

In some embodiments of the present disclosure, by depositing the amorphous buffer layer 120 on the amorphous quartz substrate 110, the stress induced by lattice mismatch is avoided, thereby addressing the peeling issues between the substrate 110 and the etch stop layer 130. And, the amorphous to amorphous structure of films can increase adhesion.

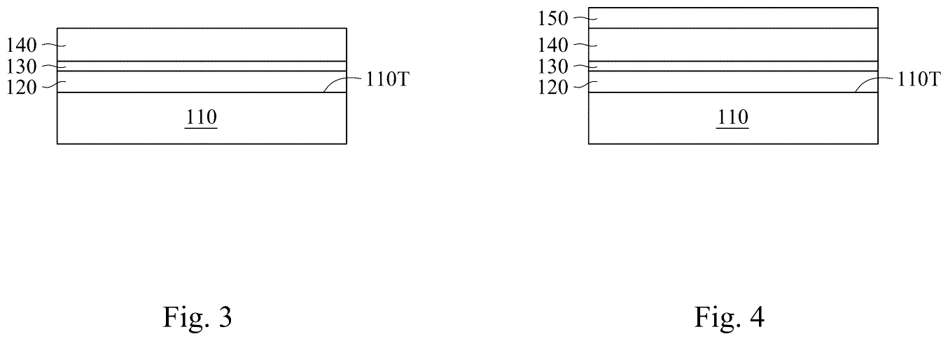

Reference is made to FIGS. 1 and 3. The method M1 proceeds to step S13 where a mold layer 140 is formed on the etch stop layer 130. The mold layer 140 may be formed from suitable optically transparent material, such as glass, quartz, an optically transparent resin such as poly (methyl methacrylate) (PMMA) or a polycarbonate resin, a transparent metal-deposited film, the like, or the combination thereof. In the case of using the optically transparent resin as the material for the mold layer 140, it is necessary to select a resin that does not dissolve in a component contained in the photocurable composition (e.g., photoresist material).

In some embodiments, the mold layer 140 may include SiO₂, Ru, Mo, W, MoSi, the like, or the combination thereof. The mold layer 140 may be a conductive layer or an insulator layer. In such embodiments, the mold layer 140 may be deposited by PVD, IBD, ALD, PEALD, CVD, PECVD, the like, or the combination thereof. In some embodiments, the mold layer 140 may include quartz. In such embodiments, the mold layer 140 may be formed by hydrothermal growth of quartz, and a polish process may be performed for planarizing a top surface of the mold layer 140 and adjusting the top surface of the mold layer 140.

Reference is made to FIG. 4. A hard mask layer 150 is deposited on the mold layer 140. The hard mask layer 150 may include a material different from that of the mold layer 140. For example, the hard mask layer 150 includes Al₂O₃, AlSiO, Ti doped SiO₂, TiO₂ doped SiO₂, Sn doped SiO₂, Mg doped SiO₂, Cu doped SiO₂, CrN, CrON, TaBO, TaBN, Cr, Ir, Nb, Ni, Pt, the like, or the combination thereof. The hard mask layer 150 may be deposited by PVD, IBD, ALD, PEALD, CVD, PECVD, the like, or the combination thereof.

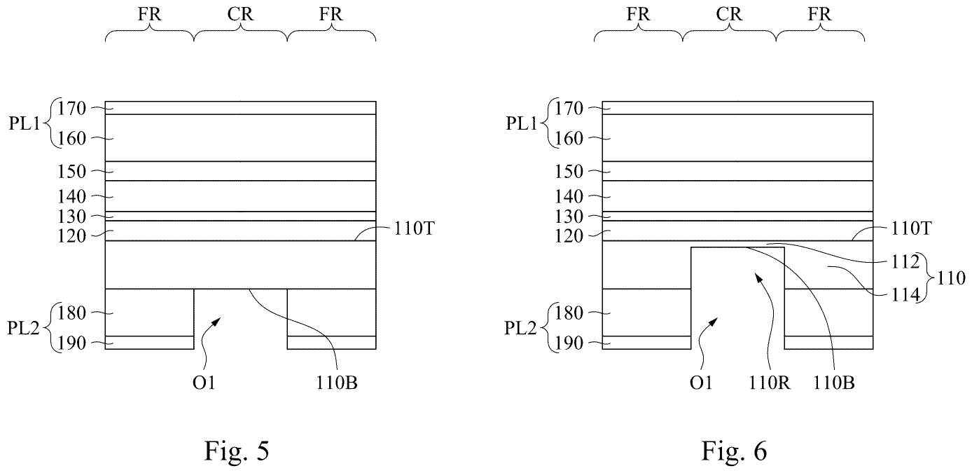

Reference is made to FIGS. 1, 5 and 6. The method M1 proceeds to step S14 where a backside of the substrate 110 is patterned to form a core-out portion 112 and a frame portion 114. Referring to FIG. 5, a protection layer PL1 is formed on the hard mask layer 150, and a protection layer PL2 is then formed on a backside surface 110B of the substrate 110. The protection layer PL1 may include a resin layer 160 and a glass layer 170 formed in a sequence. The protection layer PL2 may include a resin layer 180 and a glass layer 190 formed in a sequence. For better illustration, the substrate 110 is illustrated as having a core-out region CR and a frame region FR surrounding the core-out region CR. The patterning process may include removing a first portion of the protection layer PL2, while a second portion of the protection layer PL2 remains. The patterning process may form an opening O1 in the protection layer PL2. Thus, a first portion of the substrate 110 in the core-out region CR is exposed by the opening O1 in the protection layer PL2, and a second portion of the substrate 110 in the frame region FR is covered by the protection layer PL2. The patterning process may be referred to as the core-out process removing material from the interior of a workpiece to create a hollow or cavity, thereby shaping the workpiece. In some embodiments, the core-out process may be a computer numerical control (CNC).

The protection layer PL2 may cover the frame region FR and have an opening O1 exposing the backside surface 110B of the substrate 110 in the core-out region CR. For example, the resin layer 180 and the glass layer 190 are first formed on the backside surface 110B of the substrate 110, followed by a core-out process. Through the core-out process, the backside surface 110B of the substrate 110 in the core-out region CR is exposed by the remaining second portion of the protection layer PL2. In some embodiments, the substrate 110 may have a thickness in a range from about 5 millimeters to about 10 millimeters, and the opening O1 in the core-out region CR in the substrate 110 has a dimension in a range from about 45 millimeters to about 100 millimeters and a depth in a range from about 4 millimeters to about 6 millimeters in the substrate 110. And, a remaining portion of the substrate 110 in the core-out region CR may have a thickness in a range from about 0.5 millimeters to about 2 millimeters.

Referring to FIG. 6, the first portion of the substrate 110 in the core-out region CR is exposed by the opening O1 in the protection layer PL2 is recessed by a patterning process. The patterning process may be referred to as the core-out process. In some embodiments, the core-out process may be a computer numerical control (CNC). And, the second portion of the substrate 110 in the frame region FR is covered by the protection layer PL2. Through the patterning process, the substrate 110 is patterned to have a core-out portion 112 and a frame portion 114 surrounding the core-out portion 112, in which a thickness of the core-out portion 112 is less than a thickness of the frame portion 114. Stated differently, a backside surface of the core-out portion 112 of the substrate 110 is concave. Through the configuration, in the subsequent nanoimprint process, the substrate 110 can be pressed and bent easily. In some embodiments, a backside of the core-out portion 112 may be planarized by a grinding/polish process, thereby improving a surface uniformity of the backside of the core-out portion 112, which facilitate the subsequent UV exposure process.

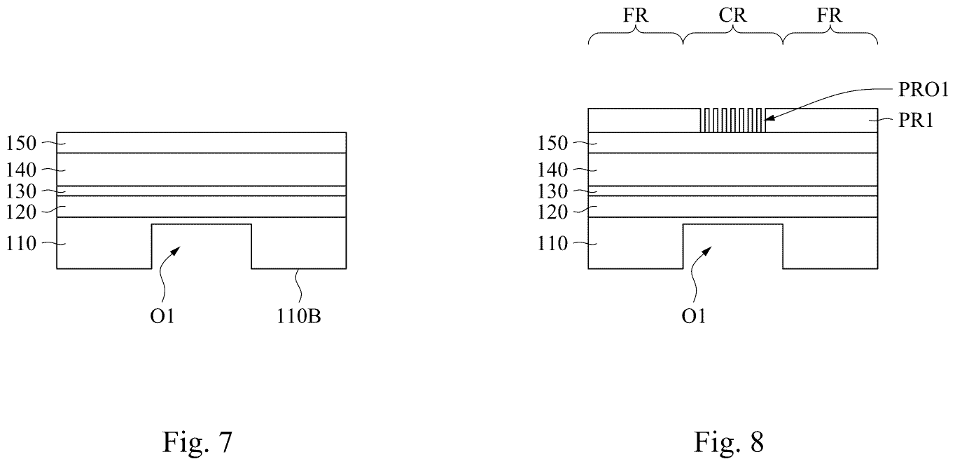

Reference is made to FIG. 7. The protection layer PL1 is removed from the hard mask layer 150, and the protection layer PL2 is removed from the backside surface 110B of the substrate 110. The removal of the protection layers PL1 and PL2 may include suitable stripping process, cleaning process, etching process, the like, or the combination thereof.

Reference is made to FIGS. 1 and 8. The method M1 proceeds to step S15 where a photoresist layer PR1 is formed on the hard mask layer 150 by suitable mask-less lithography process. For example, the mask-less lithography process may include photoresist coating, e-beam writing, post-exposure baking (PEB), developing, and other suitable process. The photoresist layer PR1 may include openings PRO1 exposing the underlying hard mask layer 150. The openings PRO1 is located in a patterning region with a dimension less than the dimension of the core-out region CR, such that an area of the patterning region is smaller than an area of the core-out region CR. For example, the patterning region may have a rectangular shape having dimensions in a range from about 20 millimeters to about 30 millimeters.

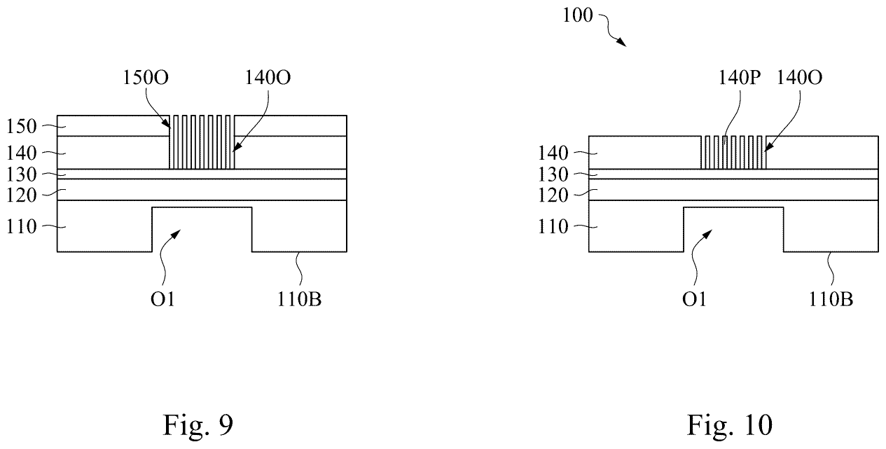

Reference is made to FIGS. 1 and 9. The method M1 proceeds to step S16 where a relief pattern (including trenches/openings 1400) is etched in the mold layer 140. At this stage, the hard mask layer 150 and the mold layer 140 are patterned to respectively have openings 1500 and trenches/openings 1400. The patterning process may include a first etching process and a second etching process following the first etching process. The first and second etching processes may include dry etch, wet etch, or the combination thereof. The first etching process etches the openings 1500 in the hard mask layer 150 by using the photoresist layer PR1 (referring to FIG. 8) as an etch mask. The second etching process etches the trenches/openings 1400 in the mold layer 140 by using the hard mask layer 150 having the openings 150O as an etch mask. The trenches/openings 140O may define plateaus (or lands) 140P of the mold layer 140. The first and second etching processes may use different etch recipes, such that the second etching process removes the mold layer 140 at a faster etch rate than it removes the hard mask layer 150. In some embodiments, the second etching process removes the mold layer 140 at a faster etch rate than it removes the etch stop layer 130, such that the etch stop layer 130 may serve as an etch stop layer during the second etching process. The etch stop layer 130 may be exposed by the trenches/openings 140O. With the etch stop layer 130, the buffer layer 120, and the substrate 110 are protected from being etched during the patterning process. For example, a top surface of the buffer layer 120 is entirely covered by the etch stop layer 130. After the patterning process, the hard mask layer 150 is removed from the mold layer 140 by a suitable cleaning/etching process. The resulted structure is shown in FIG. 10.

In some embodiments of the present disclosure, the substrate 110, the buffer layer 120, the etch stop layer 130, and the mold layer 140 in combination form a master nanoimprint mask 100. The master nanoimprint mask 100 may also referred to as a master nanoimprint template in some embodiments. In the core-out region CR, the mold layer 140 may provide a relief pattern made up of trenches/openings 1400 and the plateaus 140P. After the formation of the master nanoimprint mask 100, an e-beam particle inspection may be performed to check the master nanoimprint mask 100, in which the conductive etch stop layer 130 can avoid the charging during the e-beam particle inspection.

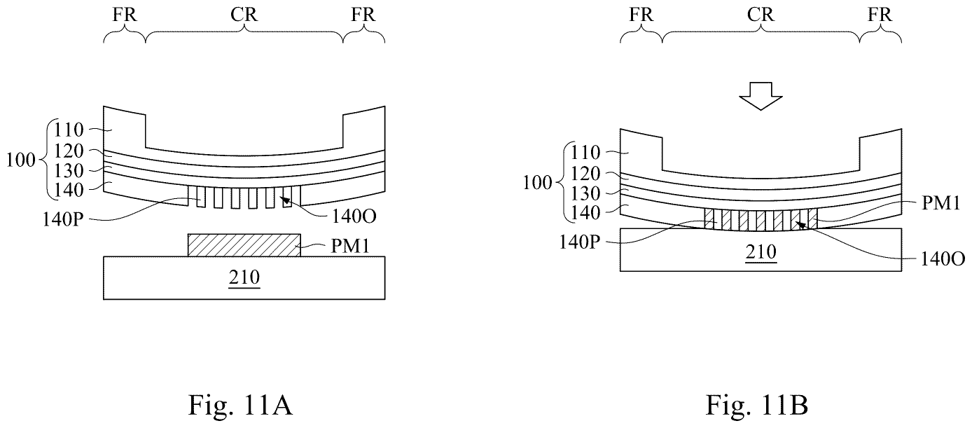

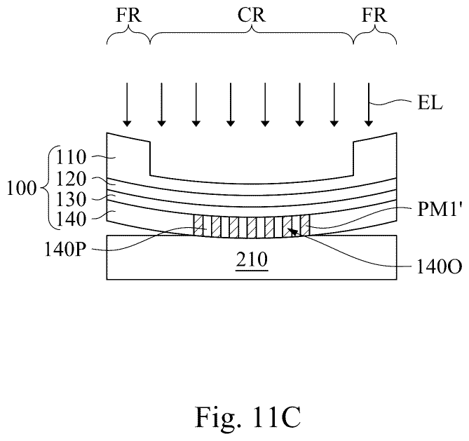

After the method M1 for manufacturing the master nanoimprint mask 100, step L1 is performed. The step L1 include performing a nanoimprint lithography process using the master nanoimprint mask 100 for a replica nanoimprint mask, in which is illustrated in FIGS. 11A-11C.

FIGS. 11A-11C are schematic views of a nanoimprint lithography process using a master nanoimprint mask 100 in accordance with some embodiments of the present disclosure. The nanoimprint lithography process may include steps in FIGS. 11A-11C. It is understood that additional steps may be provided before, during, and after the steps shown in FIGS. 11A-11C, and some of the steps described below can be replaced or eliminated for additional embodiments of the method. The order of the operations/processes may be interchangeable.

In FIG. 11A, the master nanoimprint mask 100 is aligned to a substrate 210, in which the substrate 210 is coated with an uncured photoresist material PM1. The uncured photoresist material PM1 is a photocurable composition formed by, for example, an ink jet method, a dip coating method, an air knife coating method, a curtain coating method, a wire bar coating method, a gravure coating method, an extrusion coating method, a spin coating method, or a slit scan, the like, or the combination thereof.

In the present embodiments, the substrate 110, the buffer layer 120, the etch stop layer 130, and the mold layer 140 of the master nanoimprint mask 100 may have a suitable thickness and material, such that they are transparent to the wavelength of radiation that the photoresist material PM1 is sensitive to.

In FIG. 11B, the master nanoimprint mask 100 is pressed toward the substrate 210, and the uncured photoresist material PM1 is spread out over the substrate 210, completely filling the trenches/openings 1400 between plateaus 140P of the mold layer 140.

In FIG. 11C, the photoresist material PM1 is exposed to an actinic radiation (in this case UV light) EL through the master nanoimprint mask 100. The exposure to actinic radiation EL may convert the uncured photoresist material PM1 (referring to FIG. 11B) into a cured (i.e. cross-linked) photoresist layer PM1′. After the exposure to actinic radiation EL, the master nanoimprint mask 100 is removed. The photoresist layer PM1′ may serve as an etch mask for etching materials on the substrate 210.

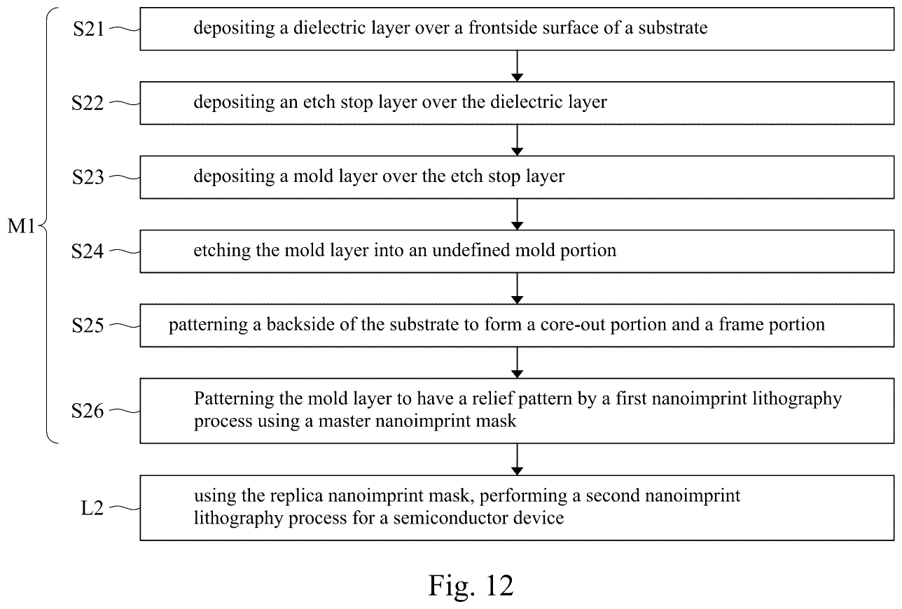

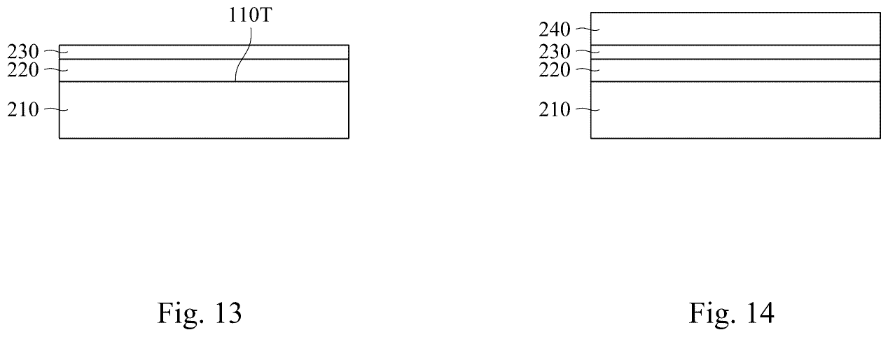

FIG. 12 is a flow chart of a method for manufacturing a replica nanoimprint mask according to some embodiments of the present disclosure. FIGS. 13-23 illustrate schematic views of intermediate stages in the manufacture of a replica nanoimprint mask 200 in accordance with some embodiments of the present disclosure. The method M2 includes steps S21-S26, followed by a nanoimprint lithography process using the master nanoimprint mask at step L2. It is understood that additional steps may be provided before, during, and after the steps S21-S26 shown in FIG. 12, and some of the steps described below can be replaced or eliminated for additional embodiments of the method. The order of the operations/processes may be interchangeable.

Reference is made to FIGS. 12 and 13. The method M2 begins at step S21, where a buffer layer 220 is deposited over a frontside surface 210T of the substrate 210. Subsequently, the method M2 proceeds to step S22, where an etch stop layer 230 is deposited over the buffer layer 220. As aforementioned, by depositing the amorphous buffer layer 220 on the amorphous quartz substrate 210, the stress induced by lattice mismatch is avoided, thereby addressing the peeling issues between the substrate 210 and the etch stop layer 230. Other details of the substrate 210, the buffer layer 220, and the etch stop layer 230 are respectively similar to the substrate 110, the buffer layer 120, and the etch stop layer 130 mentioned in the embodiments of FIG. 2, and thereto not repeated herein.

Reference is made to FIGS. 12 and 14. The method M2 proceeds to step S23, where a mold layer 240 is deposited over the etch stop layer 230. The mold layer 240 may be formed from suitable optically transparent material, such as glass, quartz, an optically transparent resin such as poly (methyl methacrylate) (PMMA) or a polycarbonate resin, a transparent metal-deposited film, the like, or the combination thereof. In the case of using the optically transparent resin as the material for the mold layer 240, it is necessary to select a resin that does not dissolve in a component contained in the curable composition.

In some embodiments, the mold layer 240 may include SiO₂, Ru, Mo, W, MoSi, the like, or the combination thereof. The mold layer 140 may be a conductive layer or an insulator layer. In such embodiments, the mold layer 240 may be deposited by PVD, IBD, ALD, PEALD, CVD, PECVD, the like, or the combination thereof. In some embodiments, the mold layer 140 may include quartz. In such embodiments, the mold layer 140 may be formed by hydrothermal growth of quartz, and a polish process may be performed for planarizing a top surface of the mold layer 140 and adjusting the top surface of the mold layer 140.

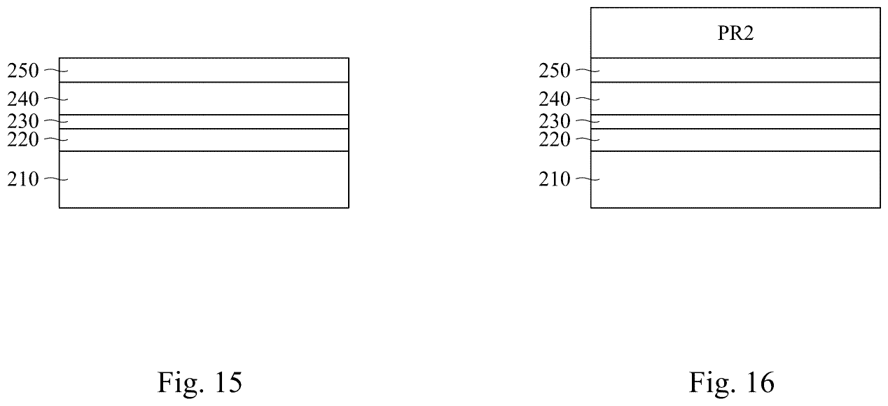

Reference is made to FIG. 15. A hard mask layer 250 is deposited on the mold layer 240. The hard mask layer 250 may include a material different from that of the mold layer 140. For example, the hard mask layer 250 includes Al₂O₃, AlSiO, Ti doped SiO₂, TiO₂ doped SiO₂, Sn doped SiO₂, Mg doped SiO₂, Cu doped SiO₂, CrN, CrON, TaBO, TaBN, Cr, Ir, Nb, Ni, Pt, the like, or the combination thereof. The hard mask layer 250 may be deposited by PVD, IBD, ALD, PEALD, CVD, PECVD, the like, or the combination thereof.

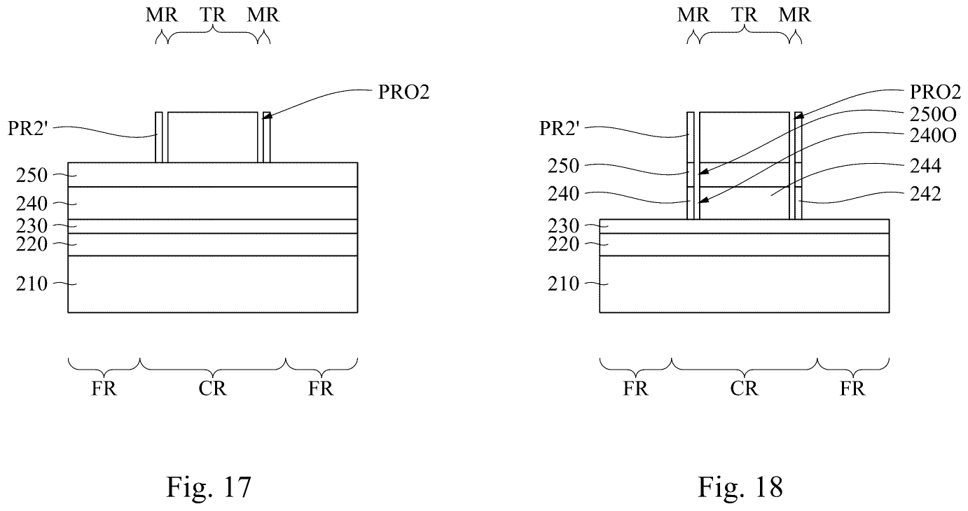

Reference is made to FIGS. 16 and 17. A photoresist layer PR2′ is formed on the hard mask layer 250 by suitable mask-less lithography process. For example, the mask less lithography process may include coating a photoresist layer PR2 (referring to FIG. 16) over the hard mask layer 250, e-beam writing, post-exposure baking (PEB), developing, and other suitable process. After being exposed, the photoresist layer PR2 (referring to FIG. 16) is cured/hardened, and referred to as photoresist layer PR2′. The resulted structure is shown in FIG. 17. The photoresist layer PR2′ may include openings PRO2 exposing the underlying hard mask layer 250. For better illustration, the substrate 210 is illustrated as having a core-out region CR and a frame region FR surrounding the core-out region CR. The photoresist layer PR2′ has the openings PRO2 exposing the frame region FR. And, in the core-out region CR, the photoresist layer PR2′ covers a pattern region TR and has the openings PRO2 defining a mark pattern in a mark region MR surrounding the pattern region TR.

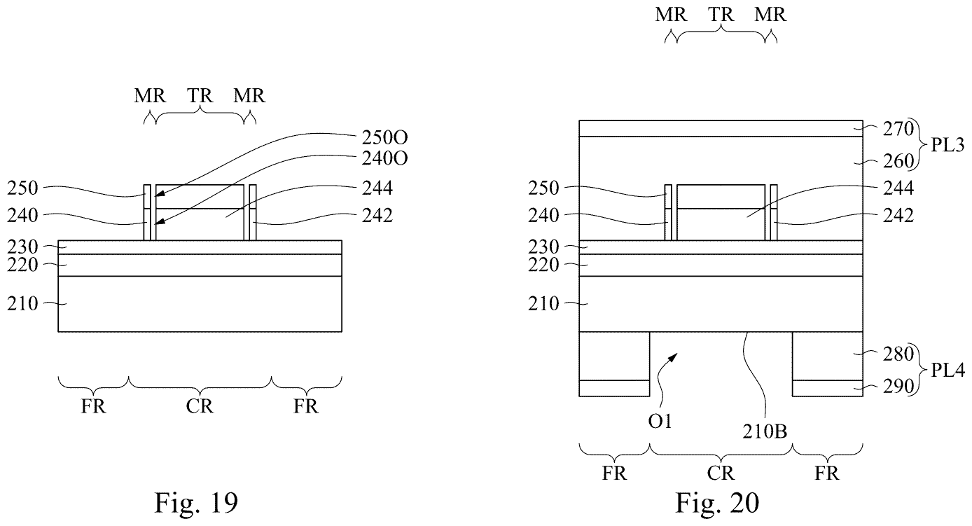

Reference is made to FIGS. 12 and 18. The method M2 proceeds to step S24, where the mold layer 240 into an undefined/unpatterned (mold) portion 244. At this stage, the hard mask layer 250 and the mold layer 240 are patterned to respectively have openings 250O and trenches/openings 240O. The patterning process may include a first etching process and a second etching process following the first etching process. The first and second etching processes may include dry etch, wet etch, or the combination thereof. The first etching process etches the openings 250O in the hard mask layer 250 by using the photoresist layer PR2′ as an etch mask. The second etching process etches the trenches/openings 240O in the mold layer 240 by using the hard mask layer 250 having the opening 250O as an etch mask. The trenches/openings 240O may define a mark pattern 242 in the mark region MR and leave an undefined/unpatterned portion 244 in the pattern region TR. The first and second etching processes may use different etch recipes, such that the second etching process removes the mold layer 240 at a faster etch rate than it removes the hard mask layer 250. In some embodiments, the second etching process removes the mold layer 240 at a faster etch rate than it removes the etch stop layer 230, such that the etch stop layer 230 may serve as an etch stop layer during the second etching process. With the etch stop layer 230, the buffer layer 220, and the substrate 210 are protected from being etched during the patterning process. The etch stop layer 230 may be exposed by the trenches/openings 240O. After the patterning process, the photoresist layer PR2′ is removed from the hard mask layer 250 by a suitable ash/stripping process. The resulted structure is shown in FIG. 19.

Reference is made to FIGS. 12, 20, and 21. The method M2 proceeds to step S25, where a backside of the substrate 210 is patterned to form a core-out portion 212 and a frame portion 214. Referring to FIG. 20, a protection layer PL3 is formed on the hard mask layer 250, and then a protection layer PL4 is formed on a backside surface 210B of the substrate 210. The protection layer PL3 may include a resin layer 260 and a glass layer 270 formed in a sequence. The protection layer PL4 may include a resin layer 280 and a glass layer 290 formed in a sequence. The protection layer PL4 may cover the frame region FR and have an opening O1 exposing the backside surface 210B of the substrate 110 in the core-out region CR. For example, the resin layer 280 and the glass layer 290 are first formed on the backside surface 210B of the substrate 210, followed by a patterning process. The patterning process is performed to remove a first portion of the protection layer PL4 in the core-out region CR, while a second portion of the protection layer PL4 in the frame region FR remains. The patterning process may be referred to as the core-out process. In some embodiments, the core-out process may be a computer numerical control (CNC). After the patterning process, the backside surface 210B of the substrate 210 in the core-out region CR is exposed by the remaining second portion of the protection layer PL4.

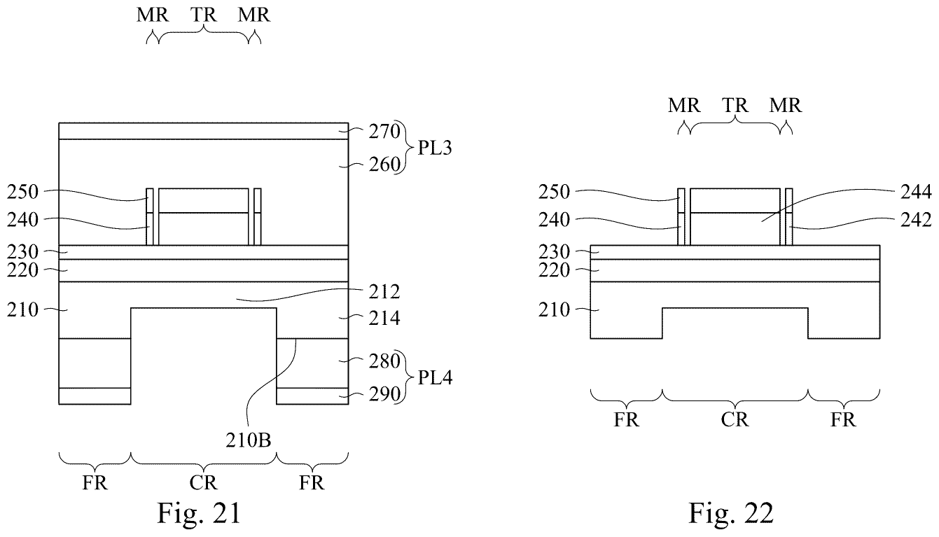

Referring to FIG. 21, a patterning process is performed to remove a portion of the substrate 210 on the backside surface 210B of the substrate 210. The patterning process may be referred to as the core-out process. In some embodiments, the core-out process may be a computer numerical control (CNC). Through the patterning process, the substrate 210 is patterned to have a core-out portion 212 in the core-out region CR and a frame portion 214 in the frame region FR, in which a thickness of the core-out portion 212 is less than a thickness of the frame portion 214. In some embodiments, a backside of the core-out portion 212 may be planarized by a grinding/polish process, thereby improving a surface uniformity of the backside of the core-out portion 212, which facilitate the subsequent UV exposure process. After patterning the substrate 210 to have the core-out portion 212 and the frame portion 214, the protection layer PL3 is removed from the hard mask layer 250, and the protection layer PL4 is removed from the backside surface 210B of the substrate 210. The resulted structure is shown in FIG. 22.

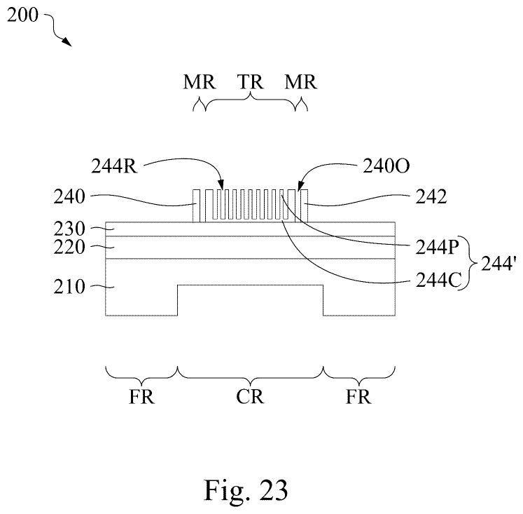

Reference is made to FIGS. 12 and 23. The method M2 proceeds to step S26, where the mold layer is patterned to have a relief pattern (e.g., made up of trenches/openings 240O and plateaus 240P) by a first nanoimprint lithography process using a master nanoimprint mask (referring to FIG. 10). The undefined/unpatterned portion 244 of the mold layer 240 (referring to FIG. 22) in the region TR is patterned to have plural recesses 244R therein. The recesses 244R may define plateaus (or lands) 244P of the mold layer 240. The patterning process may include forming a photoresist layer over the hard mask layer 250 (referring to FIG. 22) by a nanoimprint process (referring to FIGS. 11A-11C), and etching the hard mask layer 250 and the mold layer 240 (referring to FIG. 22) below the photoresist layer after forming the photoresist layer. The nanoimprint process may use the master nanoimprint mask 100 (referring to FIG. 10) as a mother template.

Etching the hard mask layer 250 and the mold layer 240 (referring to FIG. 22) may include a first etching process and a second etching process following the first etching process. The first and second etching processes may include dry etch, wet etch, or the combination thereof. The first etching process etches openings in the hard mask layer 250 (referring to FIG. 22) by using the photoresist layer formed by the nanoimprint process (referring to FIGS. 11A-11C) as an etch mask. The second etching process etches the recesses 244R in the mold layer 240 by using the hard mask layer 250 having the openings as an etch mask. The first and second etching processes may use different etch recipes, such that the second etching process removes the mold layer 240 at a faster etch rate than it removes the hard mask layer 250.

In the present embodiments, the second etching process may be controlled to stop before reaching the etch stop layer 230, such that the mold layer 240 has a thinned portion 244C below the recesses 244R and connected between the plateaus (or lands) 244P of the mold layer 240. In such embodiments, the etch stop layer 230 is not exposed by the recesses 244R.

In some other embodiments, as the second etching process removes the mold layer 240 at a faster etch rate than it removes the etch stop layer 230, the etch stop layer 230 may serve as an etch stop layer during the second etching process. In such embodiments, the recesses 244R extends through the mold layer 240 and expose the etch stop layer 230, and the thinned portion 244C of the mold layer 240 is omitted. After the patterning process, the hard mask layer 250 (referring to FIG. 23) may be removed from the mold layer 240 by a suitable cleaning/etching process.

In some embodiments of the present disclosure, the substrate 210, the buffer layer 220, the etch stop layer 230, and the mold layer 240 in combination form a replica nanoimprint mask 200. In the core-out region CR, the mold layer 240 may provide a relief pattern made up of the recesses 244R and the plateaus 244P. After the formation of the replica nanoimprint mask 200, an e-beam particle inspection may be performed to check the replica nanoimprint mask 200, in which the conductive etch stop layer 230 can avoid the charging during the e-beam particle inspection.

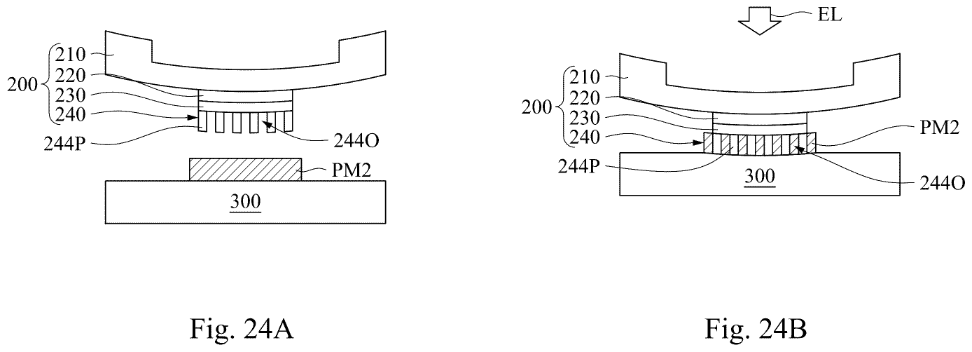

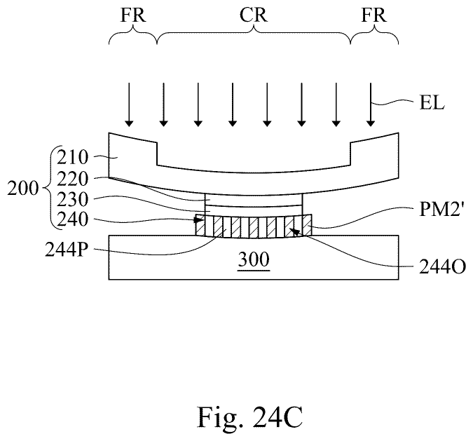

After the method M2 for manufacturing the replica nanoimprint mask 200, step L2 is performed. The step L2 include performing a nanoimprint lithography process using the replica nanoimprint mask 200 for a semiconductor device, in which is illustrated in FIGS. 24A-24C.

FIGS. 24A-24C are schematic views of a nanoimprint lithography process using a replica nanoimprint mask 200 in accordance with some embodiments of the present disclosure. It is understood that additional steps may be provided before, during, and after the steps shown in FIGS. 24A-24C, and some of the steps described below can be replaced or eliminated for additional embodiments of the method. The order of the operations/processes may be interchangeable.

In FIG. 24A, the replica nanoimprint mask 200 is aligned to a substrate 300, in which the substrate 300 is coated with an uncured photoresist material PM2.

The substrate 300 may be a semiconductor wafer. In some embodiments, the substrate 300 includes silicon (Si), germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the semiconductor layer 130 may include silicon (Si), germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. One or more layers/materials may be formed on the substrate 300. The uncured photoresist material PM2 is a photocurable composition formed by, for example, an ink jet method, a dip coating method, an air knife coating method, a curtain coating method, a wire bar coating method, a gravure coating method, an extrusion coating method, a spin coating method, or a slit scan, the like, or the combination thereof.

In the present embodiments, the substrate 210, the buffer layer 220, the etch stop layer 230, and the mold layer 240 of the replica nanoimprint mask 200 may have a suitable thickness and material, such that they are transparent to the wavelength of radiation that the photoresist material PM2 is sensitive to.

In FIG. 24B, the replica nanoimprint mask 200 is pressed toward the substrate 300, and the uncured photoresist material PM2 is spread out over the substrate 300, completely filling the trenches/openings 244O between plateaus 244P of the mold layer 240.

In FIG. 24C, the photoresist material PM2 is exposed to an actinic radiation (in this case UV light) EL through the replica nanoimprint mask 200. The exposure to actinic radiation EL may convert the uncured photoresist material PM2 (referring to FIG. 24B) into a cured (i.e. cross-linked) photoresist layer PM2′. After the exposure to actinic radiation EL, the replica nanoimprint mask 200 is removed. The photoresist layer PM2′ may serve as an etch mask for etching the layers/materials on the substrate 300.

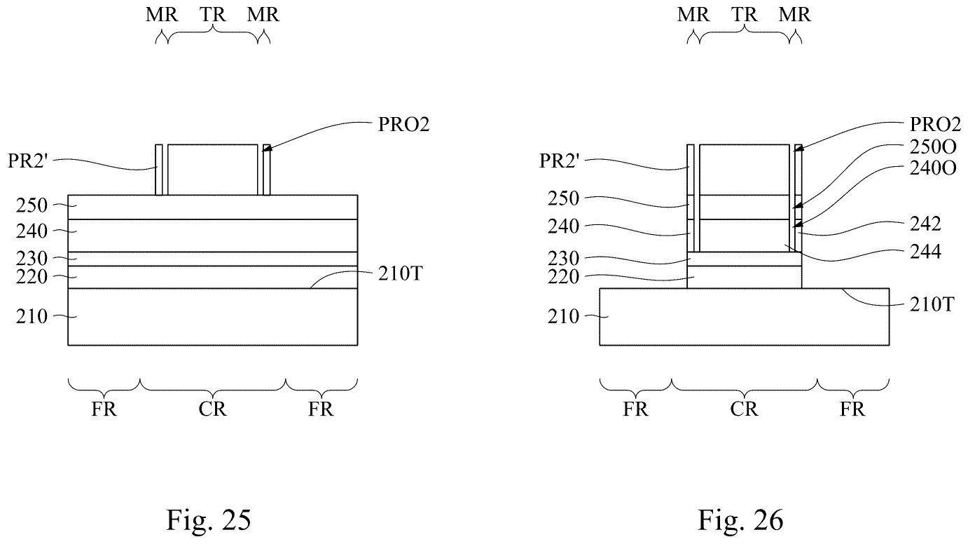

FIGS. 25-31 illustrate schematic views of intermediate stages in the manufacture of a replica nanoimprint mask 200 in accordance with some embodiments of the present disclosure. Details of the present embodiments are similar to those of FIGS. 13-23, except that the buffer layer 220 and the etch stop layer 230 are patterned. It is understood that additional steps may be provided before, during, and after the steps shown in FIGS. 25-31, and some of the steps described below can be replaced or eliminated for additional embodiments of the method. The order of the operations/processes may be interchangeable.

Reference is made to FIG. 25. As the structure shown in FIG. 17, a substrate 210 is provided, and a buffer layer 220, an etch stop layer 230, a mold layer 240, and a hard mask layer 250 are deposited on a frontside surface 210T of the substrate 210 in a sequence.

A photoresist layer PR2′ is formed on the hard mask layer 250 by suitable mask less lithography process. For example, the mask-less lithography process may include coating a photoresist layer over the hard mask layer 250, e-beam writing, post-exposure baking (PEB), developing, and other suitable process. The photoresist layer PR2′ may include openings PRO2 exposing the underlying hard mask layer 250. For better illustration, the substrate 210 is illustrated as having a core-out region CR and a frame region FR surrounding the core-out region CR. In the present embodiments, the photoresist layer PR2′ has the openings PRO2 exposing the frame region FR. And, in the core-out region CR, the photoresist layer PR2′ covers a pattern region TR and has the openings PRO2 defining a mark pattern in a mark region MR surrounding the pattern region TR.

Reference is made to FIG. 26. The hard mask layer 250, the mold layer 240, the etch stop layer 230, and the buffer layer 220 are patterned by suitable etching process. The patterning process may include a first etching process, a second etching process following the first etching process, and a third etching process following the second etching process. The first to third etching processes may include dry etch, wet etch, or the combination thereof. The first etching process etches the openings 250O in the hard mask layer 250 in the core-out region CR and etches away a portion of the hard mask layer 250 in the frame region FR by using the photoresist layer PR2′ as an etch mask. The second etching process etches the trenches/openings 240O in the mold layer 240 in the core-out region CR and etches away a portion of the mold layer 240 in the frame region FR by using the hard mask layer 250 having the openings 250O as an etch mask. The first and second etching processes may use different etch recipes, such that the second etching process removes the mold layer 240 at a faster etch rate than it removes the hard mask layer 250. In some embodiments, the second etching process removes the mold layer 240 at a faster etch rate than it removes the etch stop layer 230, such that the etch stop layer 230 may serve as an etch stop layer during the second etching process. With the etch stop layer 130, the buffer layer 120 and the substrate 110 are protected from being etched during the second etching process. The etch stop layer 130 may be exposed by the trenches/openings 1400. After the second etching process, the third etching process is performed to remove a portion of the etch stop layer 130 and a portion of the buffer layer 220 in the frame region FR, thereby exposing the frontside surface 210T of the substrate 210.

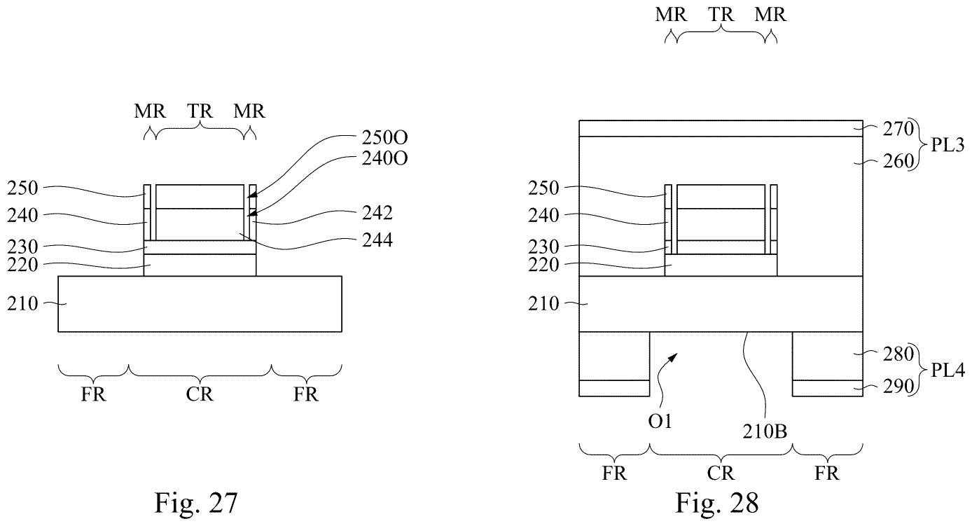

In the present embodiments, the trenches/openings 2400 in the mold layer 240 may define a mark pattern 242 in the mark region MR and leave an undefined/unpatterned portion 244 in the pattern region TR. After the patterning process, the photoresist layer PR2′ is removed from the hard mask layer 250 by a suitable ash/stripping process. The resulted structure is shown in FIG. 27.

Reference is made to FIG. 28. A protection layer PL3 is formed on the hard mask layer 250, and then a protection layer PL4 is formed on a backside surface 210B of the substrate 210. The protection layer PL3 may include a resin layer 260 and a glass layer 270 formed in a sequence. The protection layer PL4 may include a resin layer 280 and a glass layer 290 formed in a sequence. The protection layer PL4 may cover the frame region FR and have an opening O1 exposing the backside surface 210B of the substrate 110 in the core-out region CR. For example, the resin layer 280 and the glass layer 290 are first formed on the backside surface 210B of the substrate 210, followed by a patterning process. The patterning process is performed to remove a first portion of the protection layer PL4 in the core-out region CR, while a second portion of the protection layer PL4 in the frame region FR remains. The patterning process may be referred to as the core-out process. In some embodiments, the core-out process may be a computer numerical control (CNC). After the patterning process, the backside surface 210B of the substrate 210 in the core-out region CR is exposed by the remaining second portion of the protection layer PL4.

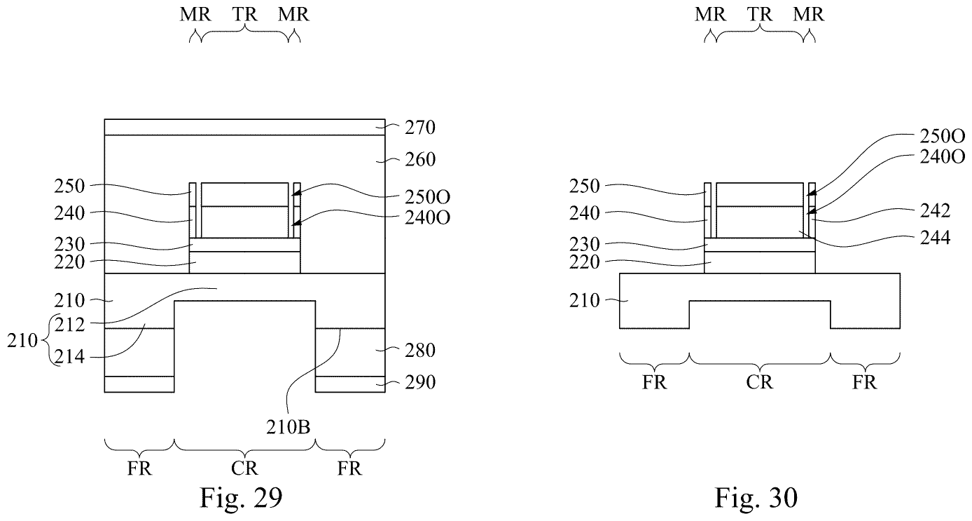

Reference is made to FIG. 29. A patterning process is performed to remove a portion of the substrate 210 on the backside surface 210B of the substrate 210. Through the patterning process, the substrate 210 is patterned to have a core-out portion 212 in the core-out region CR and a frame portion 214 in the frame region FR, in which a thickness of the core-out portion 212 is less than a thickness of the frame portion 214. The patterning process may be referred to as the core-out process. In some embodiments, the core-out process may be a computer numerical control (CNC). In some embodiments, a backside of the core-out portion 212 may be planarized by a grinding/polish process, thereby improving a surface uniformity of the backside of the core-out portion 212, which facilitate the subsequent UV exposure process. After patterning the substrate 210 to have the core-out portion 212 and the frame portion 214, the protection layer PL3 is removed from the hard mask layer 250, and the protection layer PL4 is removed from the backside surface 210B of the substrate 210. The resulted structure is shown in FIG. 30.

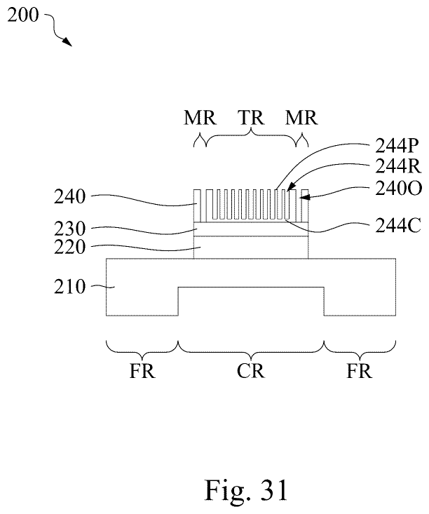

Reference is made to FIG. 31. The undefined/unpatterned portion 244 of the mold layer 240 (referring to FIG. 30) in the region TR is patterned to have plural recesses 244R therein. The recesses 244R may define plateaus (or lands) 244P of the mold layer 240. The patterning process may include forming a photoresist layer over the hard mask layer 250 (referring to FIG. 30) by a nanoimprint process (referring to FIGS. 11A-11C), and etching the hard mask layer 250 and the mold layer 240 (referring to FIG. 30) below the photoresist layer after forming the photoresist layer. The nanoimprint process may use the master nanoimprint mask 100 (referring to FIG. 10) as a mother template.

Etching the hard mask layer 250 and the mold layer 240 (referring to FIG. 30) may include a first etching process and a second etching process following the first etching process. The first and second etching processes may include dry etch, wet etch, or the combination thereof. The first etching process etches openings in the hard mask layer 250 (referring to FIG. 30) by using the photoresist layer formed by the nanoimprint process (referring to FIGS. 11A-11C) as an etch mask. The second etching process etches the recesses 244R in the undefined/unpatterned portion 244 of the mold layer 240 (referring to FIG. 30) by using the hard mask layer 250 having the openings as an etch mask. The first and second etching processes may use different etch recipes, such that the second etching process removes the mold layer 240 at a faster etch rate than it removes the hard mask layer 250.

In the present embodiments, the second etching process may be controlled to stop before reaching the etch stop layer 230, such that the mold layer 240 has a thinned portion 244C below the recesses 244R and connected between the plateaus (or lands) 244P of the mold layer 240. In such embodiments, the etch stop layer 230 is not exposed by the recesses 244R.

In some other embodiments, as the second etching process removes the mold layer 240 at a faster etch rate than it removes the etch stop layer 230, the etch stop layer 230 may serve as an etch stop layer during the second etching process. In such embodiments, the recesses 244R extends through the mold layer 240 and expose the etch stop layer 230, and the thinned portion 244C of the mold layer 240 is omitted. After the patterning process, the hard mask layer 250 (referring to FIG. 30) may be removed from the mold layer 240 by a suitable cleaning/etching process.

In some embodiments of the present disclosure, the substrate 210, the buffer layer 220, the etch stop layer 230, and the mold layer 240 in combination form a replica nanoimprint mask 200. In the core-out region CR, the mold layer 240 may provide a relief pattern made up of the recesses 244R and the plateaus 244P. Other details of the present embodiments are similar to those illustrated in the embodiments of FIGS. 13-23, and thereto not repeated herein.

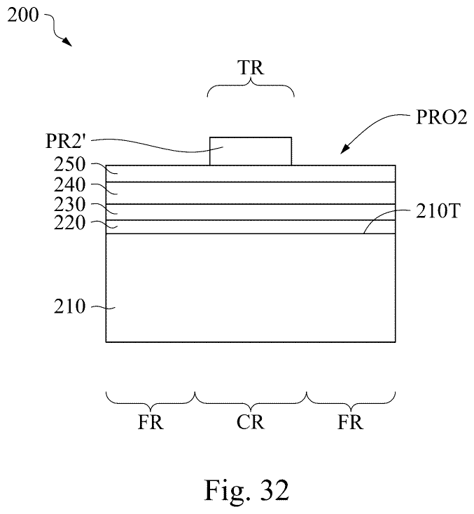

FIGS. 32-35 illustrate schematic views of intermediate stages in the manufacture of a replica nanoimprint mask in accordance with some embodiments of the present disclosure. Details of the present embodiments are similar to those of FIGS. 25-31, except that the substrate 210 is patterned to have a mesa structure 216 supporting the mold layer 240. It is understood that additional steps may be provided before, during, and after the steps shown in FIGS. 32-35, and some of the steps described below can be replaced or eliminated for additional embodiments of the method. The order of the operations/processes may be interchangeable.

Reference is made to FIG. 32. As the structure shown in FIG. 25, a substrate 210 is provided, and a buffer layer 220, an etch stop layer 230, a mold layer 240, and a hard mask layer 250 are deposited on a frontside surface 210T of the substrate 210 in a sequence. A photoresist layer PR2′ is formed on the hard mask layer 250 by suitable mask-less lithography process. For example, the mask-less lithography process may include coating a photoresist layer over the hard mask layer 250, e-beam writing, post-exposure baking (PEB), developing, and other suitable process. The photoresist layer PR2′ may include openings PRO2 exposing the underlying hard mask layer 250. For better illustration, the substrate 210 is illustrated as having a core-out region CR and a frame region FR surrounding the core-out region CR. In the present embodiments, the photoresist layer PR2′ has the openings PRO2 exposing the frame region FR, and the photoresist layer PR2′ covers a pattern region TR of the core-out region CR.

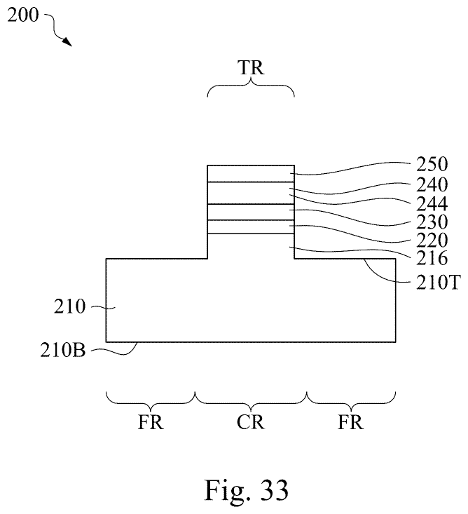

Reference is made to FIG. 33. The hard mask layer 250, the mold layer 240, the etch stop layer 230, the buffer layer 220, and the substrate 210 are patterned by suitable etching process. The patterning process may include a first etching process and a second etching process following the first etching process. The first and second etching processes may include dry etch, wet etch, or the combination thereof. The first etching process etches away a portion of the hard mask layer 250 outside the pattern region TR by using the photoresist layer PR2′ as an etch mask. The second etching process etches away a portion of the mold layer 240 outside the pattern region TR by using the hard mask layer 250 as an etch mask. The first and second etching processes may use different etch recipes, such that the second etching process removes the mold layer 240 at a faster etch rate than it removes the hard mask layer 250. After the first and second etching processes, the hard mask layer 250 and the mold layer 240 remains in the pattern region TR of the core-out region CR. The mold layer 240 in the pattern region TR may be referred to as an undefined/unpatterned portion 244.

In some embodiments, the second etching process removes the mold layer 240 at a faster etch rate than it removes the etch stop layer 230, such that the etch stop layer 230 may serve as an etch stop layer during the second etching process. With the etch stop layer 230, the buffer layer 220 and the substrate 210 are protected from being etched during the second etching process. After the second etching process, the etch stop layer 230 may be exposed. After the second etching process, using the hard mask layer 250 as an etch mask, one or more etching processes is performed to etch away a portion of the etch stop layer 130, a portion of the buffer layer 220, and portion of the substrate 210 outside the pattern region TR, thereby lowering the frontside surface 210T of the substrate 210. Through the etching processes, the substrate 210 is patterned to have the mesa structure 216 in the pattern region TR. After patterning the hard mask layer 250, the mold layer 240, the etch stop layer 230, the buffer layer 220, and the substrate 210, the photoresist layer PR2′ is removed from the hard mask layer 250 by a suitable ash/stripping process.

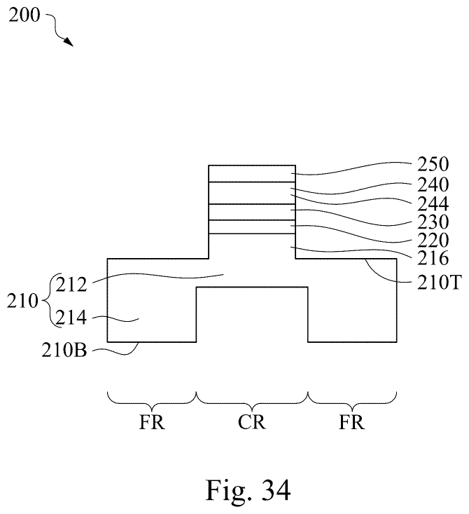

Reference is made to FIG. 34. A core-out process is performed to remove a portion of the substrate 210 on the backside surface 210B of the substrate 210. Through the core-out process, the substrate 210 is patterned to have a core-out portion 212 in the core-out region CR and a frame portion 214 in the frame region FR, in which a thickness of the core-out portion 212 is less than a thickness of the frame portion 214.

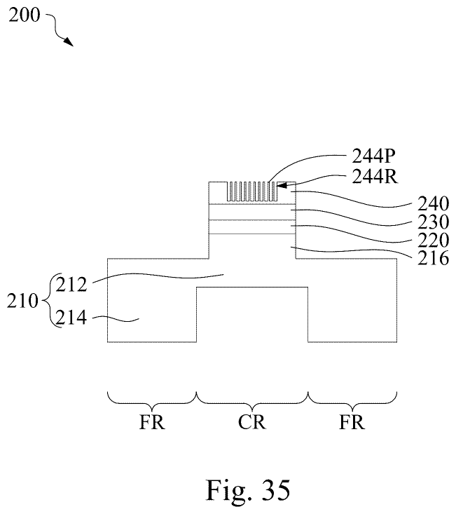

Reference is made to FIG. 35. The undefined/unpatterned portion 244 of the mold layer 240 (referring to FIG. 34) in the region TR is patterned to have plural recesses 244R therein. The recesses 244R may define plateaus (or lands) 244P of the mold layer 240. The patterning process may include forming a photoresist layer over the hard mask layer 250 (referring to FIG. 34) by a nanoimprint process (referring to FIGS. 11A-11C), and etching the hard mask layer 250 and the mold layer 240 (referring to FIG. 34) below the photoresist layer after forming the photoresist layer. The nanoimprint process may use the master nanoimprint mask 100 (referring to FIG. 10) as a mother template. Other details of the present embodiments are similar to those illustrated in the embodiments of FIGS. 25-31, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a stop layer and a buffer/adhesion/ strain layer are inserted between the substrate and the mold layer of a mask, thereby improving the thickness uniformity of the patterns in the mold layer. Another advantage is that the buffer/adhesion/ strain layer is an amorphous layer deposited on the amorphous substrate, such that the amorphous to amorphous structure can increase the adhesion between the buffer/adhesion/ strain layer and the substrate. Still another advantage is that the stop layer can be the conductive layer for e-beam particle inspection to avoid the charging during the inspection.

According to some embodiments of the present disclosure, a method for manufacturing a mask is provided. The method includes depositing a dielectric layer over a frontside surface of a substrate; depositing an etch stop layer over the dielectric layer; depositing a mold layer over the etch stop layer; patterning a backside of the substrate to form a core-out portion and a frame portion surrounding the core-out portion, wherein a thickness of the frame portion is greater than a thickness of the core-out portion; and etching a relief pattern in the mold layer over the core-out portion of the substrate until reaching the etch stop layer.

According to some embodiments of the present disclosure, a method for manufacturing a mask is provided. The method includes depositing a dielectric layer over a frontside surface of a substrate; depositing an etch stop layer over the dielectric layer; depositing a mold layer over the etch stop layer; etching the mold layer into an undefined mold portion, wherein the etch stop layer is exposed by the undefined mold portion; and patterning the substrate into a core-out portion and a frame portion surrounding the core-out portion, wherein the frame portion is thicker than the core-out portion, and the core-out portion overlaps the undefined mold portion.

According to some embodiments of the present disclosure, a nanoimprint mask is provided. The nanoimprint mask includes a substrate, a dielectric layer, a conductive layer, and a mold layer. The substrate has a core-out portion and a frame portion surrounding the core-out portion, and the frame portion is thicker than the core-out portion. The dielectric layer is over a frontside surface of the substrate. The conductive layer is over the dielectric layer. The mold layer is over the conductive layer. The mold layer comprises a relief pattern over the core-out portion of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a nanoimprint mask, comprising:
depositing a buffer layer over a frontside surface of a substrate;
depositing an etch stop layer over the buffer layer;
depositing a mold layer over the etch stop layer;
patterning a backside of the substrate to form a core-out portion and a frame portion surrounding the core-out portion, wherein a thickness of the frame portion is greater than a thickness of the core-out portion; and
etching a relief pattern in the mold layer over the core-out portion of the substrate until reaching the etch stop layer.

2. The method of claim 1, wherein etching the relief pattern in the mold layer is performed after patterning the substrate into the core-out portion and the frame portion.

3. The method of claim 1, wherein the buffer layer is amorphous.

4. The method of claim 2, wherein the etch stop layer is amorphous.

5. The method of claim 1, wherein the etch stop layer is a conductive layer.

6. The method of claim 4, wherein the etch stop layer comprises a metal.

7. The method of claim 1, wherein etching the relief pattern in the mold layer is performed such that the mold layer has a plurality of openings exposing the etch stop layer.

8. The method of claim 1, further comprising:
forming a photoresist layer over the mold layer by a mask-less lithography process, wherein etching the relief pattern in the mold layer is performed using the photoresist layer as an etch mask.

9. The method of claim 1, wherein patterning the backside of the substrate comprises:
forming a protection layer on the backside of the substrate; and
etching the substrate using the protection layer as an etch mask.

10. A method for manufacturing a nanoimprint mask, comprising:
depositing a buffer layer over a frontside surface of a substrate;
depositing an etch stop layer over the buffer layer;
depositing a mold layer over the etch stop layer;
etching the mold layer into an undefined mold portion, wherein the etch stop layer is exposed by the undefined mold portion; and
etching a backside surface of the substrate, such that the substrate has a core-out portion and a frame portion surrounding the core-out portion, wherein the frame portion is thicker than the core-out portion, and the core-out portion overlaps the undefined mold portion.

11. The method of claim 10, wherein etching the backside surface of the substrate is performed after etching the mold layer into the undefined mold portion.

12. The method of claim 10, further comprising:
after patterning the substrate into the core-out portion and the frame portion, etching a relief pattern in the undefined mold portion.

13. The method of claim 10, wherein the buffer layer is amorphous.

14. The method of claim 10, wherein the etch stop layer is a conductive layer.

15. The method of claim 10, further comprising:
etching the frontside surface of the substrate, such that the substrate has a mesa structure supporting the undefined mold portion.

16. A nanoimprint mask, comprising:
a substrate, wherein the substrate has a core-out portion and a frame portion surrounding the core-out portion, and the frame portion is thicker than the core-out portion, and;
a buffer layer over a frontside surface of the substrate;
a conductive layer over the buffer layer; and
a mold layer over the conductive layer.

17. The nanoimprint mask of claim 16, wherein the buffer layer is amorphous.

18. The nanoimprint mask of claim 16, wherein the conductive layer is amorphous.

19. The nanoimprint mask of claim 16, wherein a portion of the conductive layer is exposed by the mold layer.

20. The nanoimprint mask of claim 16, wherein the mold layer comprises a relief pattern over the core-out portion of the substrate.
